(19) United States
(12) Patent Application Publication
(10) Pub. No.: US 2022/0360038 A1
(43) Pub. Date: Nov. 10, 2022

(54) SYSTEMS AND METHODS FOR EXTERNAL MODULATION OF A LASER

(71) Applicant: ARRIS Enterprises LLC, Suwanee, GA (US)

(72) Inventor: Brian E. Ishaug, Pleasanton, CA (US)

(73) Assignee: ARRIS Enterprises LLC, Suwanee, GA (US)

(21) Appl. No.: 17/736,921

(22) Filed: May 4, 2022

Related U.S. Application Data
(60) Provisional application No. 63/184,452, filed on May 5, 2021.

(51) Int. Cl. H01S 5/00; H01S 5/12; G02F 1/17; H01S 5/10

(52) U.S. Cl. CPC H01S 5/0085; H01S 5/12; G02F 1/17; H01S 5/1028; H01S 5/34313

(57) ABSTRACT

Improved systems and methods for externally modulating a laser. Such systems may comprise a laser section and a modulator section made of an active material that selectively absorbs light from the laser section, where the operating wavelength of the laser is near the exciton absorption peak of the active material of the EAM.

### CROSS REFERENCE TO RELATED APPLICATIONS

This application claims the benefit of U.S. Provisional Patent Application Ser. No. 63/184,452 filed May 5, 2022.

### BACKGROUND

The subject matter of this application relates to systems and methods for externally modulating light from a laser, such as an Electro-modulated laser (EML) where a laser and an external Electro-absorption Modulator (EAM) are fabricated as a single device, or other similar assembly.

Optical communications systems transmit information between devices by modulating light propagated through a fiber optic cable or some other optical medium. For example, many existing optical communications systems use a laser to produce a light beam having a narrow line width spectrum and provides a mechanism for modulating that light. The modulation of the light from the laser is what carries the information in the signal. The information-carrying light is then propagated to a receiver using a single mode fiber optic cable, which can transmit signals over longer distances relative to multimode fiber.

Light from a laser is typically modulated in one of two ways—direct modulation and external modulation. A directly modulated laser uses an information-carrying signal to drive the laser, thus the output from the laser carries the modulation signal. A directly modulated optical transmitter is a cost-effective solution for many applications, however it tends to produce a relatively large amount of laser chirp, which is an undesired change in the center frequency of the laser caused by the intensity modulation that produces the information-carrying signal. At the minimum loss wavelength of standard optical fiber, this laser chirp will interact with the optical dispersion inherent in the fiber optic cable, which is the tendency of spectral components of an optical signal to travel at different velocities along the fiber. Chirp also interacts with the Raman scattering that occurs in fiber to produce additional noise at the receiver. This is commonly referred to as Interferometric Intensity Noise (IIN).

The interaction of chirp with fiber dispersion produces undesirable performance degradations, such as composite second order (CSO) distortions. Though these distortions can be corrected using an electronic circuit that pre-distorts the input signal to the laser in a way that “cancels” the CSO distortion due to the chirp/dispersion in the fiber, so as to produce the original undistorted signal at the receiver, the distortion correction has to be customized for the transmission length of fiber run between the transmitter and receiver because fiber dispersion is a function of fiber length. Therefore, this requires additional tuning during network implementation. Also, this may cause some limitations in certain applications. For example, when the light is split in the transmission path and each portion of the split light travels down to different fiber lengths, it is difficult to design a predistortion correction circuit that suits both transmission lengths. Furthermore, when a primary link and a secondary link have different link lengths, the distortion correction needs to be reset after switching occurs between the primary and secondary links. Finally, electronic distortion correction has its own limit in terms of its correction capability, which limits the total transmission link length.

An externally modulated laser transmitter, conversely, has a laser produce an unmodulated output, which is then fed into an external circuit that modulates the output. There are different types of external modulator technologies, such as a lithium niobite (LN) based Mach-Zehnder (MZ) modulator and an electro-absorption modulator (EAM). For LN MZ transmitters, the light from the light source is split equally and each portion is sent to a phase modulator that uses a voltage to modulate the phase due to an electro-optic effect. The light from the two separate paths are then combined and interfere. If the phase difference between the two light beams is zero degrees, then the maximum optical output power is achieved. If the phase difference between the two light beams is 180 degrees, then the minimum optical output power is achieved. The LN MZ based external modulator thus provides very good analog performance over long transmission distance not only because its low modulator chirp, but also because so long as the LN MZ modulator is biased at its quadrature point, it produces very low second order distortions.

However, LN MZ transmitters also suffer some drawbacks. First, the best second order distortion performance can only be achieved at a quadrature point of the modulator transfer function, and a small bias deviation from that point makes the distortion degrade very quickly. Therefore, the modulator voltage bias for the optimal performance needs to be constantly monitored and controlled because to prevent drift. Also, the modulator is bulky and costly as compared to a directly modulated transmitter.

A typical electro-absorption modulator (EAM) relies on the Franz-Keldysh effect or Quantum-Confined Stark Effect (QCSE) where the effective band gap of the semiconductor changes in response to an applied voltage. At certain wavelengths, this change in bandgap causes a change in absorption. The change in absorption is used to selectively either absorb or pass the light from the laser. Any absorbed light is converted to photocurrent, and therefore the electro-absorption modulator (EAM) works in a similar way to that of a photodetector when the appropriate bias is applied. A particular EAM may allow one bias voltage to be applied that causes the modulator to absorb all, or substantially all of the incoming light at the laser's wavelength while another applied bias voltage allows the light at the laser's wavelength to pass through transparently. Thus, alternating the bias of the EAM may produce either analog or digital signals depending on the modulation scheme.

EAM external modulation of laser transmitters have several advantages. First, the electro-absorption modulator has a much lower chirp as compared to the directly modulated DFB laser. Second, the electro-absorption modulator requires a low bias voltage and driving power for modulation. Third, the electro-absorption modulator can be integrated with a DFB laser to form a device called an EML (electro-absorption modulated laser). Because of this integration, the EML device is very small with a package similar to a normal DFB laser, and therefore very cost effective.

The change in bandgap associated with the Franz-Keldysh or the QCSE is very fast. Therefore, EAMs that rely on these effects are commonly used for high speed digital communications. However, they have drawbacks for analog communications. The main drawback is they have a very non-linear absorption versus bias curve. This is acceptable and can even be preferred in digital applications but is not desired in analog applications where a linear change in absorption over a wide bias interval is preferable.

An alternate way to design and use an EAM is to operate at a wavelength that has significant absorption at zero volts bias and the minimum amount of light will pass. Applying a positive bias will cause the EAM to become more transparent as an approximately linear function of the positive bias voltage until full transparency is reached and the maximum amount of light will pass. However, the precise wavelength setting to achieve optimum performance as well as the method to set this wavelength is presently unknown. Conversely, the optimum design for the EAM active region to get optimum performance at a desired wavelength is unknown.

For optimum EAM performance, it is desired to minimize the light leakage at 0V bias. However, setting the wavelength too long or too short will potentially result in more light leakage at 0V bias, reducing EAM performance. Increasing the EAM length can reduce the amount of leakage but may not be desirable for a number of reasons.

What is desired, therefore, is an improved externally modulated laser that reduces light leakage without increasing the length of an EAM section.

### BRIEF DESCRIPTION OF THE DRAWINGS

For a better understanding of the invention, and to show how the same may be carried into effect, reference will now be made, by way of example, to the accompanying drawings, in which:

FIG. 1 shows a diagram of an external modulation system

FIG. 2A shows a Butt-Joint Coupled (BJC) electro-absorption modulated laser.

FIG. 2B shows an Identical Layer (IL) electro-absorption modulated laser.

FIG. 3 shows an enlarged cross-sectional view of the IL electro-modulated laser of FIG. 2B.

FIG. 4 shows an exemplary Gain-Absorption spectrum of a multi-quantum well (MQW) active region of an electro-absorption modulator (EAM) section operating in reverse bias.

FIG. 5 shows an exemplary Gain-Absorption spectrum of a multi-quantum well (MQW) region of an electro-absorption modulator (EAM) section operating in forward bias.

FIG. 6 shows a preferred operating wavelength for an exemplary Gain-Absorption spectrum of a multi-quantum well (MQW) region of an electro-absorption modulator (EAM) section operating in forward bias.

### DETAILED DESCRIPTION

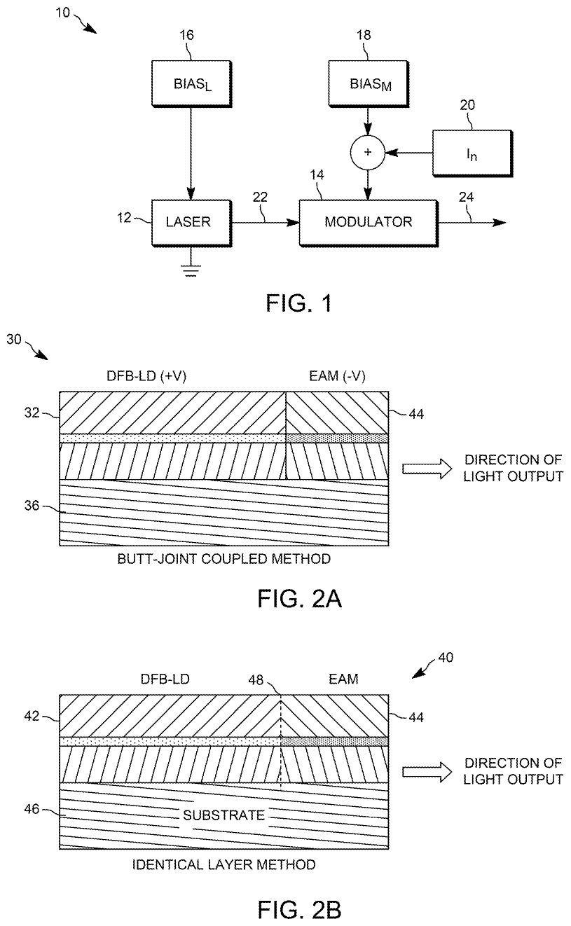

FIG. 1 schematically shows a system 10 that externally modulates a laser 12 with an external modulator 14, which may be an EAM. The laser 12 preferably produces a continuous wave (CW) output having a narrow line width spectrum around an operating frequency of the laser 12. The laser 12 is operated at an electrical bias 16 denoted as Bias_{L}. The un-modulated CW output from the laser 12 may be coupled to the external modulator 14 by optical fiber 22, or alternatively in some embodiments by free space propagation, a waveguide or other methods.

The external modulator 14 is operated at an electrical bias 18 which is denoted as Bias_{M}. An information-containing electrical signal 20 that is modulated around a mean value of 0, denoted in FIG. 1 as “IN” is also applied to modulate the bias 18 so that during modulation, the sum of the bias voltage and the modulated voltage determines how much of the optical output of the laser is transmitted through the modulator, and how much of the optical signal is absorbed and converted to electrical current. An optical output 24 is provided for delivering the modulated optical signal to a transmission network, receiver, etc.

The modulator 14 and laser 12 are typically made from direct bandgap semiconductors such as Indium Phosphide (InP), Gallium Arsenide (GaAs) and/or related materials that exhibit direct bandgap properties. The laser is typically a Distributed Feedback (DFB) laser, which produces a narrow linewidth, single-mode optical output beneficial for long distance fiber-optic communications. However, it may consist of any laser implementation capable of producing a narrow linewidth output including, but not limited to a Distributed Bragg Reflection (DBR) laser or an External Cavity laser.

One preferred embodiment of the laser 12 and modulator 14 shown in FIG. 1 may preferably be integrated into a single electronic device called an Electro-absorption Modulated Laser (EML). EMLs may be fabricated in several varieties, any of which may benefit by the embodiments disclosed herein. FIG. 2A, for example, shows a cross section of a Butt-Joint Coupled (BJC) EML 30. In the BJC EML 30, a DFB laser section 32 and an EAM section 34 are fabricated separately, then combined at a later stage by butt coupling the EAM section 34 to the laser section 32 on top of a substrate or carrier 36. The advantage of this method is that the active region of the DFB laser section 32 can be fabricated from materials and in its design optimized for the laser operation, which the active region in the EAM section 34 can be fabricated from different materials, and in different design optimized for EAM operation. However, the disadvantage is that a Butt-Joint Coupled EAM can be more costly to manufacture.

FIG. 2B shows an alternate Identical layer (IL) EML 40, where a DFB laser section 42 and an EAM section 44 are fabricated on the same substrate 46 and therefore share much of the same active region and optical confinement structure. To provide electrical isolation between the laser section 42 and the EML section 44, so that each section may be driven by independent bias signals, a channel or trench 48 is typically formed between the two sections 42 and 44. The primary advantage of an IL EML is its lower cost due to the integration of the laser 42 and EAM section 44 on the same substrate. However, there may be performance trade-offs that need to be made between the laser and EAM section because they share the same active region.

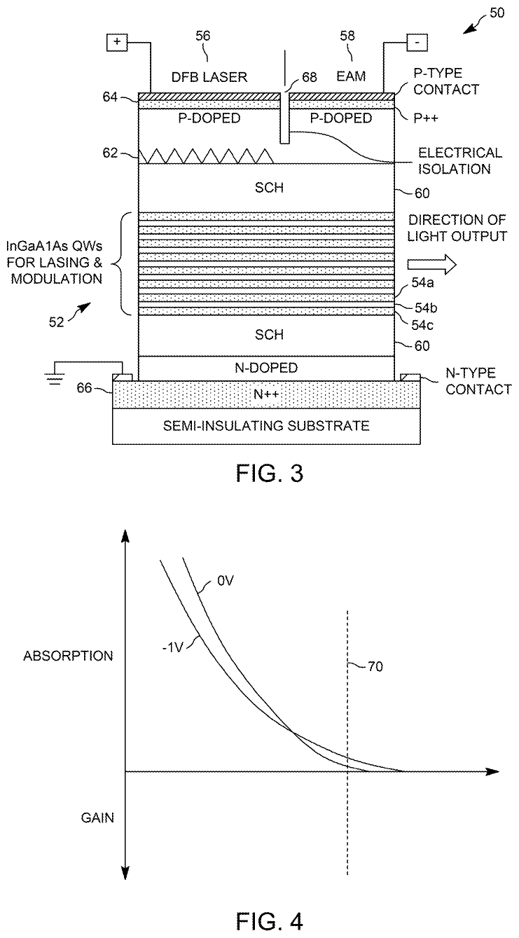

FIG. 3 shows an enlarged cross-section 50 of a typical IL EAM. The structure consists of an active region 52 of an intrinsic semiconductor material. As used in this specification, the term “intrinsic semiconductor” refers to a material that exhibits the qualities of a “pure” undoped semiconductor, although those of ordinary skill in the art will realize that the intrinsic semiconductor may be fabricated from material that contains impurities, and therefore some doping may be needed to make the semiconductive properties intrinsic.

The active region 52 preferably comprises very thin, alternating layers 54a, 54b of low band-gap energy material that is in between material with higher band-gap energy. The way the conduction and valence bands align in this structure results in the creation of energy wells in both the conduction and valence bands. When the thickness of these energy wells is in the range is a few atoms thick to a few 10s of atoms thick, quantum mechanical effects dominate, and the energy wells are referred to as Quantum Wells (QWs). The energy states contained within the these QWs are no longer equivalent to the bulk material energy state and will instead depend on the energy depth of the wells and thickness of the QWs. There are generally material system limitations that limit the ability to control the depth of the QWs, but by careful control of the thicknesses, it is possible to control the bandgap energy of the active region. As explained below, because bandgap energy is related to the gain and absorption spectrum, it is possible to tailor the active region to produce a desired optical gain and/or absorption spectrum. The “band-gap” energy of a material refers to the amount of energy input required to cause an electron to rise from a valence state to a conductive state, and conversely the amount of energy an electron must emit or release when falling from a conductive state to a valence state. When the energy that causes the electron to rise to the conduction band comes from a photon, this is referred to as photo-absorption. When the energy that is emitted is in the form of a photon, this is referred to as photoemission.

When an electron, normally in a valence state, absorbs enough energy to rise to a conductive state, it can propagate through the material in response to an electric field. It also leaves behind a hole in the valence band that behaves similarly to positively charged particle that propagates in the opposite direction in response to the same electric field. The movement of electrical current through a semiconductor may therefore also be conceptualized as the as movement of negatively charged electrons going in one direction and positively charged holes going in the opposite direction.

Light with energy higher than the bandgap energy incident on a semiconductor will be absorbed by electrons in the valence band, causing them to jump to the higher energy conductive band state, thereby creating an electron and a hole pair. If an electric field is present, the electron and hole will separate and not recombine. In the case of an EAM at 0V bias, an electric field will be present due to the built-in potential of the PN junction. This provides the electric field that separates the electron and hole pair causing them to not recombine.

At some positive bias, the electron—hole pairs will not separate because the bias applied will overcome the built-in potential of the PN junction. This will allow the electron—hole pair to recombine and release their energy. In the case of direct bandgap semiconductors such as GaAs and InP, the energy is most often released in the form of a photon with an energy equal or approximately equal to the difference in energy states between the electron and hole. This emission of a photon can be stimulated by a passing photon causing a coherent addition to power. When the number of photons being absorbed approximately equals the numbers of photons being generated by stimulated emission, you have a condition known as transparency. At a bias higher than the bias needed to overcome the built-in potential of the PN junction, additional electrons and holes will be injected into the active region. This can result in a stimulated emission rate that exceeds the absorption rate. In this state, the EAM will produce gain and the power output from the EAM can exceed the power input.

The laser section also requires a bias sufficiently high to produce gain. However, the laser requires gain that is high enough to overcome losses. It also requires optical feedback from facets or other reflection sources to “seed” the stimulated emission and create the self-sustaining condition known as lasing. By designing a structure to provide feedback at a desired wavelength of light, such as a DFB structure, a narrow linewidth laser is generated. A laser may be created with the quantum well structure of the active region 52 of the laser section 56, so long as gain overcomes loss.

The structure shown in FIG. 3 places the active region 52 between an intrinsic Separate Confinement Heterostructure (SCH) semiconductor layers 60. The SCH layers 60 are designed to confine the light propagating through the active region 52 by having a slightly higher index of refraction than the active region. Within the top SCH layer 60 in the laser section is the DFB grating 62. This grating 62 produces the selective feedback required to achieve single mode lasing operation. On the very top and bottom of the EAM shown in cross section 50 are P- and N-doped layers 64 and 66, respectively. These layers provide the source for the electrons and holes that are injected into the active region of the laser section 56 under forward bias. Forward bias is obtained by voltages applied to contacts respectively associated with the layers 54 and 56. The P- and N-doped layers 64 and 66 also provide the sink for the electrons and holes that are generated in the EAM section 58 at 0V or negative bias.

For IL type EML devices, a trench 68 is commonly etched between the DFB laser section 56 and EAM section 58 down to the intrinsic SCH layer 60 to provide electrical isolation between the laser section 56 and EAM section 58. For BJC EML lasers, this isolation is achieved either by leaving a small gap or applying an electrically insulating coating to the front facet of the laser and/or the back facet of the EAM section. These coatings are also commonly designed to have anti-reflective properties, which can help reduce optical feedback from the interface between the EAM and laser section.

By selecting an appropriate bias voltage for the laser section and the EAM section, respectively, the QWs generate light in the laser section 56 and absorb light in the EAM section 58. As explained earlier, in the laser section 56, application of a sufficient forward (+) bias will generate stimulated emission of photons of a wavelength determined primarily by the properties of the reflector 62.

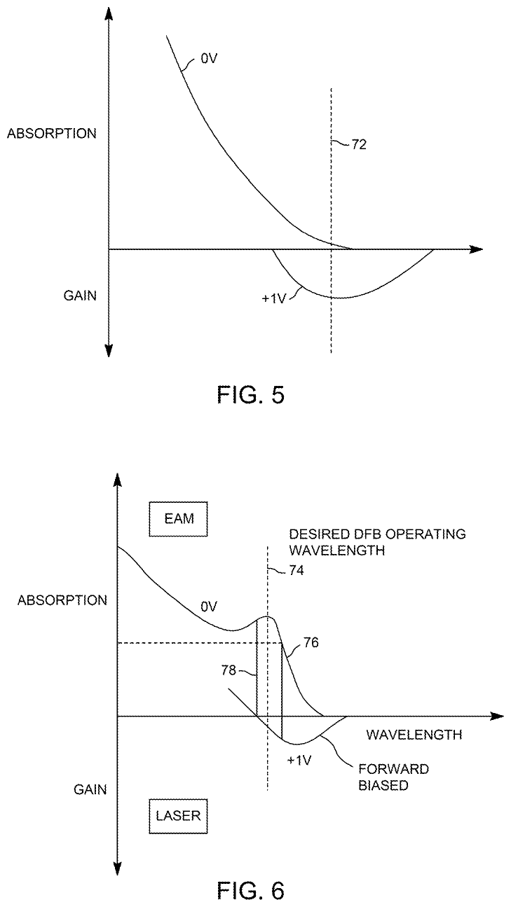

The EAM section has its bias modulated to either absorb or transmit light at the wavelength of that emitted by the laser. The modulation type adopted is typically either a negative bias modulation where the bias is modulated between 0V and some negative voltage, such as −1V, or a positive bias modulation where the bias is modulated between zero volts and a positive voltage such as +1V. These operations are illustrated in FIGS. 4 and 5, which together show a rough plot of absorption/gain as a function of wavelength for an active region at zero volts, −1 volts, and +1 volts, where an EAM section is designed to operate under reverse bias (FIG. 4) or forward bias (FIG. 5), respectively.

Referring specifically to FIG. 4, negative bias modulations set the wavelength of the laser input to the EAM long enough (low energy) so that there is approximately zero absorption at 0V bias. This is shown as reference line 70 in FIG. 4. Applying a negative bias shifts the absorption spectrum of the EAM's active region to lower energies so that it absorbs at the wavelength of the input light in an amount that depends on the amount of the negative bias. This shift in absorption spectrum at negative bias is caused by application of the electric field which “distorts” the quantum wells, causing the energy states to change, a phenomenon known as the Quantum-confined Stark Effect (QCSE). This negative bias modulation is typically adopted for digital applications because it is very fast, which is a useful property for high speed digital communications. However, the transition from the on state to the off state is highly nonlinear versus applied bias. This is not a problem for digital application and can even be an advantage, but for RF over fiber and other application that require linear operation, this non-linearity causes problems such as intermodulation distortion that can significantly degrade performance.

Positive bias modulation, conversely, is typically used for analog applications such as optical RF-over-fiber. Referring to FIG. 5, in a positive bias modulation scheme, the wavelength of the input laser is set short enough (input energy high) to be mostly absorbed at 0V bias. This is shown as reference line 72 in FIG. 5. Under this condition, light that is injected into the EAM will be absorbed and a photo-current will be generated at 0V bias. When a positive bias is applied, the active region of the EAM becomes more transparent with increasing positive bias because electron-hole pairs are not being extracted from the active region, which allows them to recombine and stimulate emission. When the stimulated emission rate matches the absorption rate, full transparency results. At the forward bias required to achieve transparency, the current will be zero or perhaps slightly positive because all the photo-generated carriers are effectively reinjected into the active region and only a small additional injection of carriers may be needed to overcome carrier losses such those caused by non-radiative recombination and/or spontaneous emission. At transparency, the optical output power from the EAM will approximately equal the optical input power.

Between 0V and the bias required to achieve transparency, the optical output power will be nearly linearly dependent on the current extracted from the EAM section. Furthermore, the current extracted from the EAM section will be largely linearly dependent upon the voltage applied to the EAM, achieving a nearly linear relationship between light output power and EAM input voltage. Because of this primarily linear relationship between EAM input voltage and optical output power, a modulated electrical signal that is applied to the EAM will be reproduced as an optical power modulation with low distortion, which is important for applications such as RF-over-fiber.

As noted, at 0V bias as shown in forward-biased implantation as seen in FIG. 5, the output optical power may not be completed extinguished because of saturation of the absorption coefficient. If the output optical power is not fully extinguished, there will be a reduction in the maximum modulation depth, which reduces performance. A longer EAM section can help reduce the minimum optical output power obtained and thus maximize modulation depth. However, a longer EAM may not be optimal for various reasons. An optimal design minimizes the output optical power at 0V bias with minimal EAM length.

The present inventor realized that the absorption/gain spectrum of a material in an active region exhibits a localized “exciton absorption peak,” which results from an artifact in the quantum well structure where electron-hole pairs are weakly bound together in the QW structure. This peak is observable at or near room temperature in the absorption spectrum of most QW and MQW active region designs. In a preferred embodiment, the operating wavelength 74 of the laser section 56 of an EML or laser and EAM system is preferably determined based on the exciton absorption peak of the material comprising the active region of the EAM, at room temperature or another ambient temperature in which the EAM is intended to operate (e.g., an ambient temperature surrounding a node or optical network unit in a communications network). In some preferred embodiments, the EAM may be operated in a forward bias manner. In another preferred embodiment, the operating wavelength 74 of the laser section 56 of an EML is set near or at the exciton absorption peak at zero volts. Notably, as can be seen in FIG. 6, the wavelength of the exciton absorption peak 76 at zero volts also corresponds to the wavelength that, at +1 volts, gain is occurring as well. This may be useful in many applications in which it is desired to output more optical power than what is input into the EAM section. Thus, a further advantage of the implementation illustrated in FIG. 6 is that it allows the EAM optical output power to exceed the optical input power, and the maximum modulated optical output power can exceed the optical input power. Therefore, for purposes of this specification and the claims, the terminology “near the exciton absorption peak” of the active region of an EML refers to a range of wavelengths surrounding the exciton absorption peak indicated by area 78, i.e., the region surrounding the peak 76 of the 0-volt curve where absorption is at or above the inflection point at which absorption increases with increasing wavelength, and for which at the “fully on” positive bias (+1 volts in FIG. 6) zero absorption and/or gain occurs. In FIG. 6 this region is denoted with reference number 78.

This localized peak represents a maximum absorption coefficient of the active region material for any given length of an EAM, as can be seen in FIG. 6, deviating from this peak reduces absorption which effectively must be compensated by increasing the EAM length. Thus, setting the operating wavelength of an EML's laser at or near the exciton absorption peak allows for short EAM section lengths, minimizes light leakage at 0V bias, and maximizes the linear optical output power as a function of the drive current operating range of the EAM section.

There may be more than 1 exciton peak present in the absorption spectrum at or near room temperature (or other ambient temperature for the EML) depending on the QW or MQW active region structure. Multiple peaks are caused by the presence of carriers with different effective masses, the most common of which are light holes and heavy holes. The excitons formed by light holes and heavy holes may have different binding energies, which results in slightly different absorption peak wavelengths. In the event of multiple exciton peaks in the absorption spectrum, the lasing wavelength can be set to the peak that is at the shortest wavelength, the exciton peak closest to the absorption band edge or any peak in-between, provided the condition of transparency or near transparency can be obtained at that wavelength under positive bias.

At the forward bias required to achieve transparency, the extracted current will be at or near 0 and the optical output power will be equal or nearly equal to the optical input power. Further increase of the forward bias will result in current injection into the active region of the EAM, which may result in optical gain. This gain can result in the optical output power from the EAM section exceeding the optical input power. The increase in optical output power will be primarily related to the injected current until the gain saturates. In this manner, linear or near linear operation can be extended to a maximum optical output power that exceeds the optical input power to the EAM section.

Although the foregoing description used an EML as an exemplary device by which to illustrate the systems and methods disclosed in the present application, those of ordinary skill in the art will appreciate that these systems and methods may be used in other arrangements. As one example, the disclosed systems and methods may be used in an arrangement where a laser and an EAM are separately fabricated, and the laser supplies light to the EAM via an optical fiber or other transmission medium such as air, and the EAM modulates that light.

It will also be appreciated that the invention is not restricted to the particular embodiment that has been described, and that variations may be made therein without departing from the scope of the invention as defined in the appended claims, as interpreted in accordance with principles of prevailing law, including the doctrine of equivalents or any other principle that enlarges the enforceable scope of a claim beyond its literal scope. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. The word “comprise” or a derivative thereof, when used in a claim, is used in a nonexclusive sense that is not intended to exclude the presence of other elements or steps in a claimed structure or method.

1. An apparatus comprising a laser and an EAM having an active region, where the laser produces an optical output at an operating wavelength, the EAM selectively absorbs optical power from the laser at the operating wavelength in an amount based upon a bias voltage applied to the EAM, and where the operating wavelength of the laser is near the exciton absorption peak of the active region.

2. The apparatus of claim 1 comprising an Electro-Modulated Laser (EML).

3. The apparatus of claim 1 comprising a Butt Joint Coupled (BJC) EML.

4. The apparatus of claim 1 comprising an Identical Layer (IL) EML.

5. The apparatus of claim 1 operated in forward bias mode.

6. The apparatus of claim 5 where the EAM section absorbs approximately all of the optical power produced by the laser section at zero volts.

7. The apparatus of claim 5 where the EAM section absorbs approximately none of the optical power produced by the laser section at a positive bias.

8. The apparatus of claim 5 where the EAM section exhibits gain on the optical power produced by the laser at a positive bias.

9. A method for fabricating an Electro-Modulated Laser (EML), the method comprising:
forming a substrate segmented into a laser section and an EAM section electrically isolated from each other, the laser section and the EAM section each including an active region activated by voltage applied to p-doped and n-doped layers; and
a grating that provides feedback in an operating wavelength of the laser section, the operating wavelength based on the exciton absorption peak of the active region.

10. The method of claim 9 used to fabricate a Butt Joint Coupled (BJC) EML.

11. The method of claim 9 used to fabricate an Identical Layer (IL) EML.

12. The method of claim 9 fabricated to operate in forward bias mode.

13. The method of claim 12 where the EAM section is fabricated to absorb approximately all of the optical power produced by the laser section at zero volts.

14. The method of claim 12 where the EAM section is fabricated to absorb approximately none of the optical power produced by the laser section at +1 volts.

15. The method of claim 12 where the EAM section is fabricated to exhibit gain on the optical power produced by the laser at +1 volts.

16. The method of claim 9 where the active region is surrounded by Separate Confinement Heterostructure (SCH) semiconductor layers, and the grating is embedded in one of the SCH layers.

17. A method of fabricating an externally modulated laser transmitter, the method comprising:
fabricating a laser configured to output light at an operating wavelength; and
fabricating an Electro-absorption Modulator (EAM) having an active region with an exciton absorption peak, the EAM configured to absorb a variable amount of the output light of the laser based on a selectively variable voltage applied to the EAM, where the operating wavelength of the laser is near the exciton absorption peak of the EAM.

18. The method of claim 17 including the step of fabricating the laser with a grating configured to provide the operating wavelength of the laser.

19. The method of claim 17 where the externally modulated laser transmitter is formed as an Electro-Modulated Laser (EML) where the laser and the EAM share the same active region.

20. The method of claim 17 where the laser and the EAM are fabricated separately and assembled so that the laser provides light to the EAM through a transmission medium comprising a selective one of an optical cable or air.
